(19) United States
(12) Patent Application Publication
(10) Pub. No.: US 2012/0094146 A1
(43) Pub. Date: Apr. 19, 2012

(54) Metallic Composite Material

(76) Inventors: Michael David Hardy, Cumberland, RI (US); Chenchung Steve Chang, Attleboro, MA (US)

(21) Appl. No.: 13/185,958

(22) Filed: Jul. 19, 2011

Related U.S. Application Data
(60) Provisional application No. 61/365,584, filed on Jul. 19, 2010.

(51) Int. Cl. B32B 15/01; H05K 13/00

(52) U.S. Cl. 428/649; 29/592.1

(57) ABSTRACT

A roll bonded, composite metallic material utilizing a Magnesium (Mg) core to take advantage of its extreme light weight. The clad composite consist of roll bonded metal layers such as Al, stainless steel, copper and titanium on the surfaces of Mg. A multitude of clad combinations are available to combine the unique surface properties of various alloys to suit the particular application or design needs, with the light weight and strength characteristics of Mg.

### PRIORITY CLAIM

This application is based upon and claims the benefit of priority from U.S. Provisional Application No. 61/365,584 filed on Jul. 19, 2010, the contents of which are expressly incorporated herein by reference.

### BACKGROUND OF THE INVENTION

The present invention relates to the field of electronic devices. More particularly, packaging materials for electronic devices such as notebooks, cell phones, PDAs, etc, require light weight, good strength, high stiffness, flexibility to apply various surface treatments, and suitability for forming processes. In even greater particularity the present invention relates to packaging materials, for electronic devices, having a magnesium core.

Electronic devices have applied common metallic packaging materials such as aluminum and stainless steels. Meanwhile, less common materials such as titanium and magnesium have seen limited application due to various reasons. Table 1 shows the empirical comparison of these materials for their merits regarding electronic packaging applications.

| | | Stiffness | | | Sur- | | |
|---|---|---|---|---|---|---|---|
| | Den- | Elastic | Tensile | Mohs | face | | |
| | sity | Modulus | Strength | Hard- | Treat- | Join- | |
| Metals | g/cm³ | GPa | MPa | ness | ment | ing | Cost |
| Stainless | 7.78 | 193 | 740 | 6.5 | VG | VG | Low |
| Copper | 8.94 | 120 | 370 | 3.0 | Fair | Fair | Fair |
| Nickel | 8.91 | 200 | 700 | 4.0 | VG | VG | High |
| Titanium | 4.51 | 116 | 716 | 6.0 | G | Fair | Very |
| | | | | | | | High |
| Aluminum | 2.70 | 70 | 245 | 2.75 | VG | VG | Low |
| Magnesium | 1.74 | 45 | 260 | 2.5 | Poor | Poor | High |

### SUMMARY OF THE PRESENT INVENTION

It is an object of the present invention to provide an electronic packaging application material which combines light weight (low density), high strength, high stiffness, and allows a multitude of surface treatment options. Magnesium alloys are among the lightest materials commonly available, however, issues associated with surface finishing as well as a lack of surface treatment options due to the extremely reactive nature of Magnesium have prevented Magnesium from being the material of choice for the packaging of portable electronic devices.

Composite materials combining multiple layers of metallic materials in strip form, and have seen many applications in many industrial, commercial and consumer devices. It is an object of the present invention to provide a packaging material comprising a combination of layers of metals including Magnesium which enables electronic device design flexibility, and thus provide the appearance and functional attributes which are not achievable by monolithic metals.

These and other objects and advantages of the invention will become apparent from the following detailed description of the preferred embodiment of the invention.

### BRIEF DESCRIPTION OF THE DRAWINGS

A clad composite metal is depicted in the accompanying drawings which form a portion of this disclosure and wherein:

FIG. 1 is a diagrammatic view of the core layer and outer layers being roll bonded into a composite material.

FIG. 2 and sectional view showing the core layer and the outer and inner layer wherein the thickness of the layers is not to scale.

### DESCRIPTION OF THE PREFERRED EMBODIMENT

Referring to the Figures or a clearer understanding of the invention, it may be seen that the preferred embodiment of the invention contemplates a roll bonded, composite metallic material 10 utilizing a magnesium core 12 to take advantage of its extreme light weight. The clad composite consist of roll bonded metal layers such as aluminum, stainless steel, copper and titanium on the surfaces of magnesium A multitude of clad combinations are available to combine the unique surface properties of various alloys to suit the particular application or design needs, with the light weight and strength characteristics of Mg. Further, it is to be understood that the housing material is susceptible to conventional forming as necessary to serve as a housing for hand held devices as well as larger devices.

EXAMPLES: The Figures are exemplary of all of the examples although the thickness of each layer is not limited by the figure. Likewise, although FIG. 2 is shaded for three different metals, it should be understood from the following description that a variety of combinations may be employed. In the figures the center layer 10 is always magnesium. The “inner” layer is designated as 12 and the outer layer is designated as 14. Various metals may be selectively used in layers 12 and 14. A Stainless/Mg/Al clad combination can provide light weight and high strength, with the desirable stainless steel surface finish from the stainless steel layer 14, while the Al layer 12 provides the option for joining processes on the inside.

An Al/Mg/Al clad combination produces a clad strip with very low weight with an Al surface which allows the existing surface finish processes to be employed. A Ti/Mg/Al clad provides good strength and surface hardness from the Ti layer 14 with the Al inside layer 12 for joining process.

A Cu/Mg/Al clad provides a unique reddish surface appearance that is attractive for certain design and weighty applications. Copper, with its very high thermal conductivity, also has the advantage of high rate of heat dissipation to reduce hot spots in the portable electronic device.

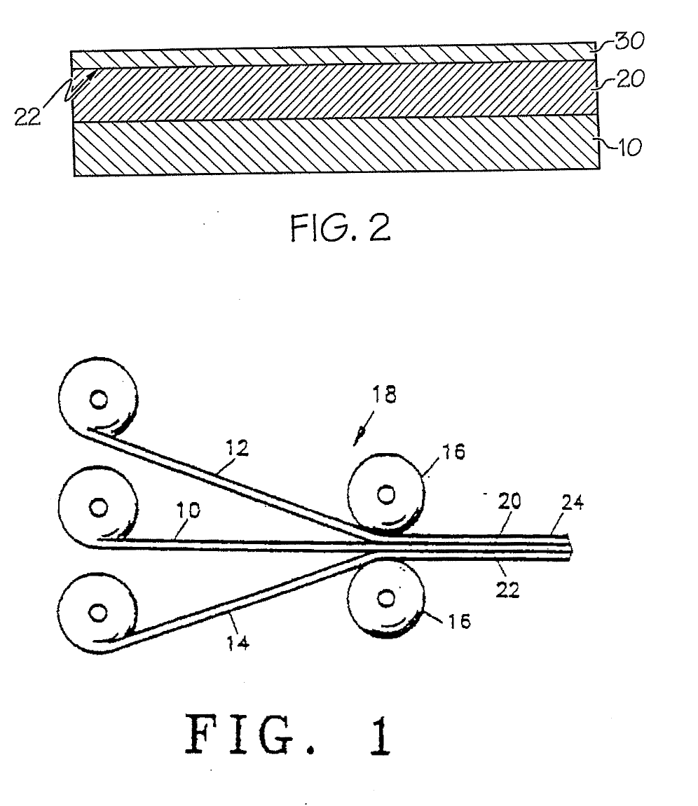

In this invention, a cold roll bonding process as shown in FIG. 1 is used to produce Mg cored composites with surface layers consisting of Al and Aluminum alloys, stainless steel and stainless alloys, titanium and titanium alloys, copper and copper alloys, or Ni and Ni alloys. The portion of Mg in the composite, presented as percent of the total clad thickness can vary from 5 to 95%. But ideally the range will be 30 to 90% since if there is too little Mg, no significant weight reduction is realized. If there is too much Mg, the effect of strengthening will not be significant. The surface layers 14 and 16 usually contain one Al layer 16 and this is usually deployed for the inside for joining purpose.

The other surface layer can be Ti, for its light weight, high strength and high hardness; Al, for its light weight, low cost, and surface appearance; copper, for its unique appearance and thermal properties; Ni, for corrosion resistance and surface appearance; Stainless steel, for high strength, high hardness and surface appearance.

The thickness of each surface layer can be varied from about 3% to about 30%. If it is too small, then the strengthening effect will not be significant. If it is too high, the increased weight will offset the beneficial low density of Mg.

The cold roll bonding process does not require heating of the Mg layer and avoids the formation of Mg oxide that prevents the formation of true metallurgical bond between the layers.

It is to be understood that the form of the invention shown is a preferred embodiment thereof and that various changes and modifications may be made therein without departing from the spirit of the invention or scope as defined in the following claims.

What is claimed is:

1. A clad metal composite for use as a packaging material for electronic devices comprising a core layer of magnesium, an inner layer for the inside of said housing comprised of aluminum or aluminum alloy, and an outer layer for the outside of said housing comprised of a metal selected from the group consisting of titanium, stainless steel, aluminum, aluminum alloys, titanium alloys, copper, nickel and nickel alloys, wherein said layers are bonded to each other in a cold rolling process such that no magnesium oxide layer is formed in bonding said layers.

2. A clad metal composite as described in claim 1 wherein said core layer comprises from about 5% to about 95% of the thickness of said clad metal composite.

3. A clad metal composite as described in claim 2 wherein said inner layer comprises from about 3% to about 30% of the thickness of said clad metal composite.

4. A clad metal composite as defined in claim 1 wherein said core layer comprises from about 30% to about 90% of the thickness of said clad metal composite.

5. A clad metal composite as described in claim 4 wherein said inner layer comprises from about 3% to about 30% of the thickness of said clad metal composite.

6. A clad metal composite as described in claim 5 wherein said outer layer comprises from about 3% to about 30% of the thickness of said clad metal composite.
